(19) United States
(12) Patent Application Publication
(10) Pub. No.: US 2015/0194417 A1
(43) Pub. Date: Jul. 9, 2015

(54) Snapback Inhibiting Clamp Circuitry For Mosfet ESD Protection Circuits

(71) Applicant: Silicon Laboratories Inc., Austin, TX (US)

(72) Inventor: Jeremy C. Smith, Austin, TX (US)

(73) Assignee: Silicon Laboratories Inc., Austin, TX (US)

(21) Appl. No.: 14/149,112

(22) Filed: Jan. 7, 2014

(51) Int. Cl. H01L 27/02

(52) U.S. Cl. CPC H01L 27/0248

(57) ABSTRACT

Circuit configurations and related methods are disclosed that may be implemented to protect circuitry from adverse effects of transistor snapback that may occur during ESD events. The circuitry and methods may be implemented as part of distributed ESD rail clamping circuitry that includes ESD circuit elements that are coupled to power nodes or supply rails and not to signal nodes or signal pads of the circuitry in a manner that reduces parasitic loading on signal pads to reduce or substantially eliminate NMOS and/or PMOS transistor snapback occurrence, while at the same time providing rail-clamping capability during occurrence of ESD events. Using the disclosed circuitry and methods, at least a portion of ESD current may be diverted by clamp circuitry from or to a supply rail to reduce voltage differential across the sources of CMOS output transistors relative to their bulk terminals in a manner that reduces forward biasing of parasitic BJTs present at each of the CMOS output transistors, thus reducing or substantially eliminating occurrence of transistor snapback during an ESD event.

### FIELD OF THE INVENTION

This invention relates to circuitry and, more particularly, to electrostatic discharge (ESD) protection circuitry.

### BACKGROUND OF THE INVENTION

FIG. 1 illustrates conventional signal output circuitry 100 having multiple signal output circuit segments 160₁ to 160_{N}, and that is configured with a distributed ESD circuit configuration. In particular, each circuit segment 160 of output circuitry 100 includes a signal output signal pad 102 that is coupled to an output signal node 107 of a respective output buffer circuit that includes complementary metal-oxide semiconductor (CMOS) driver circuitry coupled between positive supply rail V_{DD} and negative supply rail V_{SS} as shown. Each output buffer circuit includes a PMOS output transistor 110 and a NMOS output transistor 112 that each have a gate coupled to an internal output control circuit 114. Each signal pad 102 is coupled at node 107 between the PMOS output transistor 110 and the NMOS output transistor 112 of each buffer circuit, and at a second node between ESD diodes 106 and 108 that are in turn coupled in series between the V_{DD} and V_{SS} rails as shown. As further illustrated, each of signal output circuit segments 160₁ to 160_{N} is configured with local ESD clamp circuitry that includes a local clamp control circuit 130 that is coupled to provide a local clamp control output 121 to the gate of a local NMOS clamp transistor 118, which itself is coupled between between V_{DD} and V_{SS} rails by respective local clamp conductive elements 117 and 119. Main clamp circuitry 170 is also provided that includes main clamp control circuit (dV/dt) 120 that is coupled to produce clamp control output 126 to the gate of a NMOS main clamp transistor 122 that is coupled between V_{DD} and V_{SS} rails by respective local clamp conductive elements 127 and 129. Clamp control output 126 from main clamp control circuit 120 is also coupled to control operation of each of local clamp control circuits 130 as shown. Main clamp circuitry 170 also includes a pad 128 coupled to supply rail V_{DD} that is present for purposes of supplying power from an external source to the chip. Pad 128 is usually present in main clamp circuitry 170 but may be located at other locations along the V_{DD} supply rail.

Still referring to FIG. 1, main clamp control circuit (dV/dt) 120 is implemented by edge-rate sensing circuitry, that is configured to sense the presence of the occurrence of a ESD event on any signal pad 102 of circuit segments 160, via coupling through ESD diodes 106 to V_{DD} line or via coupling through ESD diodes 108 to the V_{SS} line, by measuring the rate of change in voltage between V_{DD} and V_{SS} rails over time. In the absence of any ESD event (i.e., normal operating voltage range exists between V_{DD} and V_{SS} rails), the output of main clamp control circuit 120 on clamp control line 126 is low and NMOS main clamp transistor 122 remains open so that no current is conducted between V_{DD} and V_{SS} rails by main clamp conductive elements 127 and 129. Each of local clamp control circuits 130 is implemented by buffering and control circuitry, that is configured to maintain a low output at node 121 when clamp control line 126 is low. Thus, as long as clamp control line 126 remains low, the output of each of local clamp control circuits 130 also remains low so that each local NMOS local clamp transistor 118 remains open and no current is conducted between V_{DD} and V_{SS} rails by local clamp conductive elements 117 and 119.

Occurrence of a positive ESD event (relative to V_{DD} and V_{SS} rails) on a signal pad 102 of a given circuit segment 160 (e.g., such as the illustrated ESD event 190 on signal pad 102₁) causes a rise in voltage versus time (dV/dt) between V_{DD} and V_{SS} rails via conduction through ESD diode 106. This voltage rise between V_{DD} and V_{SS} rails is detected by main clamp control circuit 120. Main clamp control circuit responds to this detected condition by providing a high signal to clamp control line 126 that causes NMOS main clamp transistor 122 to close (turn on) such that transistor 122 shunts the charge generated by the ESD event 190 from V_{DD} to V_{SS} via a shunt formed by main clamp conductive elements 127 and 129. At the same time the high signal on clamp control line 126 is also provided from main clamp control circuit 120 to the local clamp control circuit 130 of each circuit segment 160 as shown. Each of local clamp control circuits 130 responds to presence of a high signal on clamp control line 126 by producing a high signal output 121 to a corresponding NMOS local clamp transistor 118 that closes (turns on) to shunt the charge generated by the ESD event 190 as current I_{ESD} from V_{DD} to V_{SS} via corresponding local clamp conductive elements 117 and 119. Thus, the charge from an ESD event is shunted as current I_{ESD} in a simultaneous distributed manner through the conductive elements 127 and 129 of main clamp circuitry 170 as well as through conductive elements 117 and 119 of each of the local clamp circuitries within each circuit segment 160. This distributed shunting of ESD event 190 by main clamp circuitry 170 and local clamp circuitry of each circuit segment 160 minimizes adverse effects of V_{DD} and V_{SS} rail bus resistances 115 and 116. Such rail resistances can otherwise cause too high voltage potentials within the integrated circuit for a given ESD discharge current level if the main clamp circuitry 170 was the sole shunt for the ESD current, risking potential ESD damage to the circuit segment struck by the ESD event and possibly other parts of circuitry 100. Resistors 124 represent the inherent resistance in the local clamp control line 126. However, resistors 124 do not cause the voltage drops caused by resistors 115 and 116 since negligible currents flow in clamp control line 126.

Still referring to FIG. 1, when an ESD event 190 strikes at a given output signal pad 102₁ current travels through ESD diode 106₁ to the V_{DD} rail and them back to V_{SS} through distributed current flow as previously described. This produces a corresponding voltage potential at node 107₁ and also at the drain of NMOS output transistor element 112₁. The magnitude of the voltage potential on node 107₁ and the drain of the NMOS transistor 112₁ depends on the magnitude of the applied ESD current and on the values of resistors 115 and sizes of local clamp transistors 118 and the main clamp transistor 122. In general, great care must be taken to keep the magnitude of the drain voltage of transistor 112₁ below certain critical limits, so as not to cause physical damage in the integrated circuit. As the magnitude of the drain voltage of NMOS transistor 112₁ increases, avalanche breakdown of the drain to substrate junction begins to occur, which creates electrons and holes. Holes flowing in the substrate create an elevation in the substrate potential in the vicinity of the NMOS transistor, inducing a voltage drop across the base and emitter of the parasitic NPN bipolar junction transistor (BJT) 103 that is present at the NMOS output transistor element 112₁. An induced voltage drop exceeding from about 0.6 to about 0.7 volts from local substrate to source of transistor element 112₁ forward biases the parasitic NPN BJT 103 of the NMOS output transistor 112₁ and causes conduction of parasitic snapback current across the parasitic BJT 103 and NMOS output transistor 112₁ from node 107₁ to the Vss rail. A similar snapback condition can occur in parasitic NPN BJTs of other NMOS transistors 112 of other circuit segments 160, e.g., in response to a positive ESD strike occurring at corresponding signal pads 102 of the other circuit segments 160. Further, snapback may similarly occur at PNP BJTs of PMOS transistors 110 in response to negative ESD strikes (relative to V_{SS} and V_{DD} rails) occurring at signal pad/s 102. Snapback current flow can occur despite the distributed clamping action of circuitry 100, and can cause permanent thermal damage to signal output circuitry 100 and breakdown of the circuit devices. In conventional circuits, snapback characteristics of MOSFET transistors are controlled by semiconductor process-related parameters such as junction profile, breakdown voltage, substrate resistance, etc. which are typically not under the control of the circuit designer.

### SUMMARY OF THE INVENTION

Disclosed herein are circuit configurations and related methods that may be implemented to protect circuitry (e.g., such as signal output circuitry or any other circuitry subject to undesirable snapback) from adverse effects of transistor snapback that may occur during ESD events. In one embodiment, the disclosed circuitry and methods may be employed to protect any type of output transistor/s subject to fatal snapback I-V characteristics including, but not limited to, advanced CMOS transistors, high voltage (HV) drain extended MOS (DeMOS) transistors, etc. and any other types of fragile output transistors. The disclosed circuitry and methods may be advantageously implemented using external circuit elements, the design of which are under the control of circuit designers. This allows snapback protection to be implemented using circuit design, and in one embodiment without varying or modifying semiconductor processing parameters for a circuit device.

The disclosed circuitry and methods may also be implemented in one embodiment as part of ESD rail clamping circuitry, e.g., as part of a rail clamping ESD protection network which is distributed across several neighboring circuit segments. In such an embodiment, ESD circuit elements may be coupled to power nodes or supply rails and not to signal nodes or signal pads of the circuitry in a manner that reduces parasitic loading on signal pads to reduce or substantially eliminate NMOS and/or PMOS transistor snapback occurrence, while at the same time providing rail-clamping capability during occurrence of ESD events. In this regard, at least a portion of ESD current may be diverted from or to a power supply rail/s in a manner that acts to reduce voltage differential across a CMOS output transistor during the occurrence of an ESD event, e.g., to elevate voltage at the source of a NMOS output transistor element relative to a struck signal output pin during the occurrence of a positive ESD event (e.g., during signal pad voltage elevation event), and/or to reduce voltage at the source of a PMOS output transistor element relative to a struck signal output pin during the occurrence of a negative ESD event (e.g., during signal pad voltage reduction event). In either case, ESD current may in one embodiment be diverted by snapback inhibiting clamp circuitry from or to a supply rail to reduce voltage differential across CMOS output transistors in a manner that reduces forward biasing of emitter-base junctions of the parasitic BJTs present at each of the CMOS output transistors, thus reducing or substantially eliminating occurrence of transistor snapback during an ESD event.

In one respect, disclosed herein is a semiconductor circuit device, including: at least first and second supply rails having opposite polarity; at least one N-type metal-oxide-semiconductor (NMOS) or P-type metal-oxide-semiconductor (PMOS) transistor coupled between the first and second supply rails; a resistive element coupled between the at least one transistor and the first supply rail with a current diversion node coupled between the at least one transistor and the resistive element; local clamp circuitry coupled between the current diversion node and the second supply rail, the local clamp circuitry being configured to selectively shunt current between the second supply rail and the first supply rail through the current diversion node and the resistive element in response to an electrostatic discharge (ESD) event; and a signal pad coupled between the first and second supply rails and also coupled between the at least one transistor and the second supply rail.

In another respect, disclosed herein is a method, including: detecting occurrence of an electrostatic discharge (ESD) event on a signal pad coupled between first and second supply rails having opposite polarity; and selectively shunting current between the second supply rail and the first supply rails through a current diversion node and a resistive element of local clamp circuitry in response to the ESD event, the resistive element being coupled between at least one N-type metal-oxide-semiconductor (NMOS) or P-type metal-oxide-semiconductor (PMOS) transistor and the first supply rail with the current diversion node coupled between the at least one transistor and the resistive element, and the at least one transistor being further coupled between the first and second supply rails with the signal pad coupled between the at least one transistor and the second supply rail.

### BRIEF DESCRIPTION OF THE DRAWINGS

FIG. 1 illustrates conventional signal output circuitry configured with a distributed ESD circuit configuration.

FIG. 2 illustrates signal output circuitry configured according to one exemplary embodiment of the disclosed circuitry and methods.

FIG. 3 illustrates signal output circuitry configured according to one exemplary embodiment of the disclosed circuitry and methods.

FIG. 4 illustrates signal output circuitry configured according to one exemplary embodiment of the disclosed circuitry and methods.

### DESCRIPTION OF ILLUSTRATIVE EMBODIMENTS

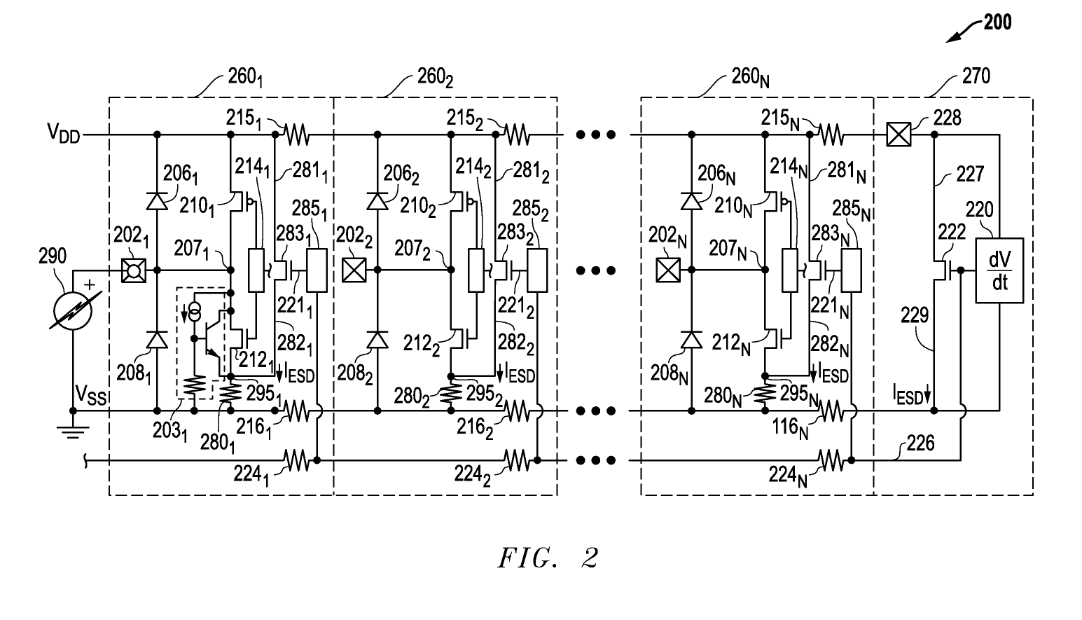

FIG. 2 illustrates one exemplary embodiment of signal output circuitry 200 having multiple signal output circuit segments 260₁ to 260_{N}, and that is further configured with an anti-snapback distributed ESD circuit configuration according to the disclosed circuitry and methods. In this embodiment, each circuit segment 260 of output circuitry 200 includes a signal output signal pad 202 that is coupled to an output signal node 207 of a respective output buffer circuit that includes complementary metal-oxide semiconductor (CMOS) buffer circuitry coupled between V_{DD} and V_{SS} rails as shown. Each output buffer circuit includes a PMOS output transistor 210 and a NMOS output transistor 212 that each have a gate coupled to an internal output control circuit 214. Each signal pad 202 is coupled at node 207 between the PMOS output transistor 210 and the NMOS output transistor 212 of each buffer circuit, and at a second node between ESD diodes 206 and 208 that are in turn coupled in series between the V_{DD} and V_{SS} rails as shown.

As further illustrated, each of signal output circuit segments 260₁ to 260_{N} is configured with local snapback inhibiting clamp circuitry that includes a respective local clamp control circuit 285 that is coupled to provide a local clamp control output 221 to the gate of a local NMOS clamp transistor 283. As further shown each local NMOS clamp transistor 283 itself is coupled between respective conductive elements 281 and 282 so as to divert ESD current (I_{ESD}) from V_{DD} to a respective source voltage elevation node (or current diversion node) 295 positioned between a source of the respective NMOS output transistor 212 and a respective voltage elevation resistive element 280 in a manner that acts to elevate voltage at the source of the NMOS output transistor element 212 relative to a struck signal output pin during the occurrence of a positive ESD event 290 in a manner described further herein. Main clamp circuitry 270 is also provided as shown, and includes main clamp control circuit (dV/dt) 220 that is coupled to produce clamp control output 226 to the base of a NMOS main clamp transistor 222 that is coupled between V_{DD} and V_{SS} rails by respective local clamp conductive elements 227 and 229. Clamp control output 226 from main clamp control circuit 220 may also coupled to control operation of each of local clamp control circuits 285 as further described herein. Main clamp circuitry 270 also includes a pad 228 coupled to supply rail V_{DD} that may be present for purposes of supplying power from an external source to the chip. Pad 228 is usually present in main clamp circuitry 270 but may be located at other locations along the V_{DD} supply rail.

Still referring to FIG. 2, main clamp control circuit (dV/dt) 220 may be implemented by any circuit configuration that is suitable for sensing the presence of the occurrence of a ESD event on any signal pad 202 of circuit segments 260, e.g., by measuring the rate of change in voltage between V_{DD} and V_{SS} rails over time. Examples of suitable ESD event-sensing circuitry includes, but is not limited to, RC triggered high-pass or low-pass circuits which drive inverter stages to buffer and condition the detected signal. In the absence of the occurrence of any ESD event (i.e., normal operating voltage range exists between V_{DD} and V_{SS} rails), the output of main clamp control circuit 220 on clamp control output 226 is low and NMOS main clamp transistor 222 remains open so that no current is conducted between V_{DD} and V_{SS} rails by main clamp conductive elements 227 and 229. Each of local clamp control circuits 285 may include any switching element circuitry that is suitable for maintaining a low output 221 when clamp control output 226 from main clamp control circuit 220 is also low. Thus, as long as clamp control output 226 remains low, the output of each of local clamp control circuits 285 also remains low so that each local NMOS local clamp transistor 283 remains open and no current is conducted from V_{DD} rail to source voltage elevation node 295 by local clamp conductive elements 281 and 282.

As shown in FIG. 2, occurrence of a positive ESD event (relative to V_{DD} and V_{SS} rails) on a signal pad 202 of a given circuit segment 260 (e.g., such as the illustrated ESD event 290 on signal pad 202₁) causes a rise in voltage versus time (dV/dt) between V_{DD} and V_{SS} rails via conduction in ESD diode element 206₁. This voltage rise between V_{DD} and V_{SS} rails is detected by main clamp control circuit 220. Main clamp control circuit responds to this detected condition by providing a high signal to clamp control output 226 that causes NMOS main clamp transistor 222 to close (turn on) such that transistor 222 shunts the charge generated by the ESD event 290 from V_{DD} to V_{SS} via a shunt formed by main clamp conductive elements 227 and 229. At the same time the high signal on clamp control output 226 is also provided from main clamp control circuit 220 to the local clamp control circuit 285 of each circuit segment 260 as shown. Each of local clamp control circuits 285 responds to presence of a high signal on clamp control output 226 by producing a high signal output 221 to a corresponding NMOS local clamp transistor 283 that closes (turns on) to divert the charge generated by the ESD event 290 as current I_{ESD} from V_{DD} to node 295 via corresponding local conductive elements 281 and 282. In this way, the charge from a positive ESD event is simultaneously diverted as current I_{ESD} to nodes 295 to elevate voltage of the source of each NMOS output transistor 212 relative to the local substrate potential of NMOS output transistor 212 thus reducing or substantially eliminating the possibility of occurrence of NMOS transistor snapback At the same time, the ESD charge is dissipated by this routing of I_{ESD} in a simultaneous distributed manner through conductive elements 281 and 282 of each of the local clamp circuitries within each circuit segment 260, as well as shunted by conductive elements 227 and 229 of main clamp circuitry 270 to minimize adverse effects of V_{DD} and V_{SS} rail bus resistances 215 and 216.

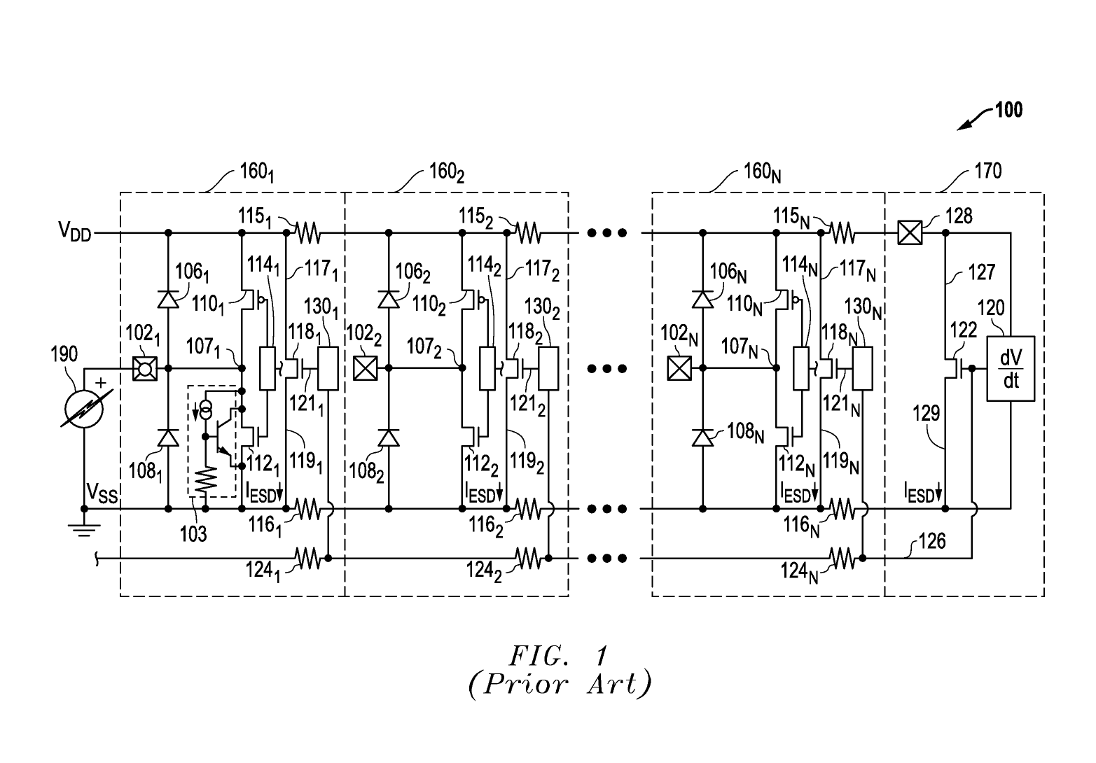

Referring to FIG. 2 in more detail, when a positive ESD event 290 strikes at a given output signal pad 202₁, a positive potential is created for current travel to the corresponding output signal node 207₁ of circuit segment 260₁ and to the drain of NMOS output transistor element 212₁ that is coupled to signal pad 202₁ at node 207₁. However, current simultaneously flows onto positive supply rail V_{DD} away from node 207₁ through ESD diode 206₁ to NMOS local clamp transistor 283₁ and is diverted to node 295₁ (and nodes 295 in other respective circuit segments 260) that is coupled between the source of NMOS output transistor 212₁ and voltage elevation resistive element 280₁ (which itself is coupled to negative supply rail V_{SS}). This current to node 295₁ from the V_{DD} supply rail induces a potential on node 295₁ through resistive element 280₁. Resistive element 280₁ may be sized and configured to provide sufficient positive voltage elevation at the source of NMOS transistor 212₁ coupled to node 295₁ to reduce or substantially eliminate occurrence of parasitic snapback across NMOS transistor 212₁ by reducing the bulk to source voltage (or equivalently the base to emitter voltage) drop across the parasitic NPN transistor 203₁ contained in NMOS output transistor element 212₁ during the occurrence of positive ESD event 290. The reduction in the base to emitter voltage of parasitic NPN transistor 203₁ prevents the forward biasing of the parasitic BJT 203₁, while at the same time allows sufficient conductivity of I_{ESD} to negative supply rail V_{SS} through resistive element 280₁ (and nodes 280 in other respective circuit segments 260) to distributively dissipate charge from ESD event 290. Thus, ESD current is prevented from entering node 207₁ due to damaging breakdown of NMOS transistor 212₁, while at the same time ESD charge is dissipated. The presence of a local clamp transistor 283 between each of nodes 295 and V_{DD} has the advantage of reducing capacitive parasitic loading on the output node 207 of each of the respective circuit segments 260 of FIG. 2 as compared to coupling local clamp transistors 118 directly to the output node 107 of each of the circuit segments 160 in the conventional configuration of FIG. 1.

With regard to the exemplary embodiment of FIG. 2 it will be understood that resistive elements 280 may be any suitable component (resistor or other resistive component) or combination of resistive components that provide a desired electrical resistance to current flow during a positive ESD event 290 without interfering with the operation of a NMOS output transistor 212 during normal output buffer circuitry operation, and while at the same time allowing sufficient conductivity of I_{ESD} to negative supply rail V_{SS} through resistive elements 280 to dissipate charge in a distributed manner from ESD event 290. In this regard, resistive elements 280 may be formed from drawn layers in a semiconductor process such as diffusion, polysilicon or metal layers and in one embodiment may exhibit a resistance value of from about 3 to about 30 ohms depending on the signaling requirements, it being understood that resistive elements 280 may have values greater than about 30 ohms or less than about 3 ohms in other embodiments. It will also be understood that the above description of configuration and function of components of circuit segment 260₁ is exemplary and representative of similar components of each of other circuit segments 260₂ to 260_{N}.

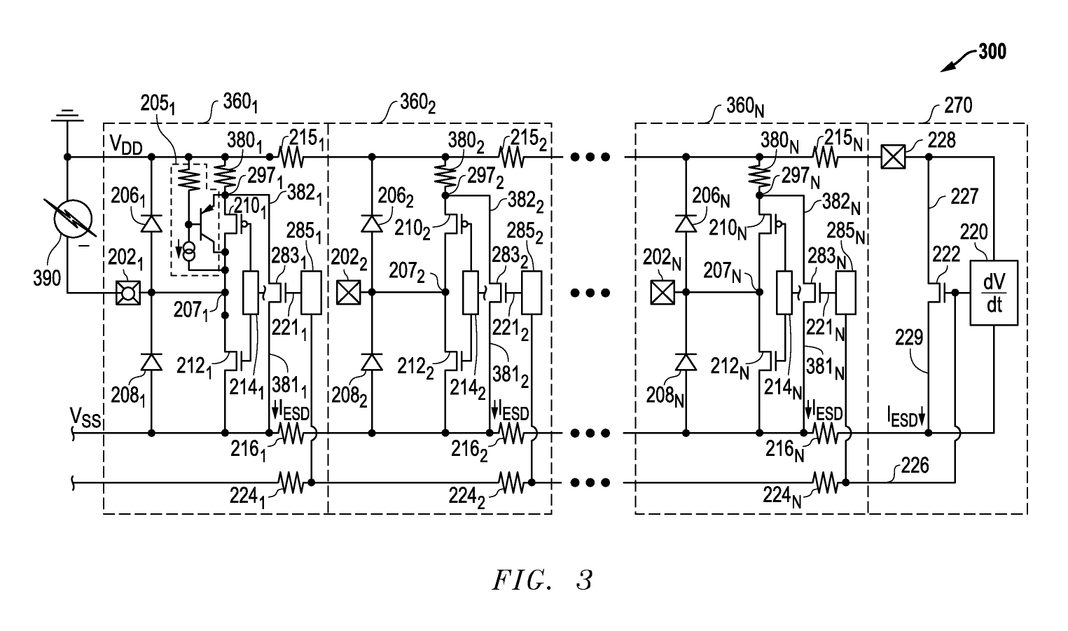

FIG. 3 illustrates another exemplary embodiment of a signal output circuitry 300 having multiple signal output circuit segments 360₁ to 360_{N} and CMOS output circuitry configured similarly to circuitry 200 of FIG. 2, except this time provided with a snapback inhibiting clamp circuit configuration to protect the PMOS (PNP) output transistor 210 of each of output circuit segments 360₁ to 360_{N} from parasitic snapback during occurrence of a negative ESD event on one of output signal pads 202. As further illustrated, each of signal output circuit segments 360₁ to 360_{N} is configured with local snapback inhibiting clamp circuitry that includes a respective local clamp control circuit 285 that is coupled to provide a local clamp control output 221 to the gate of a local NMOS clamp transistor 283. As further shown, each local NMOS clamp transistor 283 itself is coupled between respective conductive elements 381 and 382 so as to divert ESD current (I_{ESD}) from V_{DD} through a respective source voltage reduction node (or current diversion node) 297 positioned between a source of the respective PMOS output transistor 210 and a respective a respective voltage reduction resistive element 380 and in a manner that acts to reduce voltage at the source of the PMOS output transistor element 210 relative to its bulk terminal (i.e., nwell) during the occurrence of a negative ESD event 390 on output pin 202₁ in a manner described further herein.

As further shown in FIG. 3, the occurrence of a negative ESD event (relative to V_{SS} and V_{DD} rails) on a signal pad 202 of a given circuit segment 360 (e.g., such as the illustrated ESD event 390 on signal pad 202₁) causes a rise in voltage versus time (dV/dt) between V_{DD} and V_{SS} rails. This voltage rise between V_{DD} and V_{SS} rails is detected by main clamp control circuit 220 and main clamp control circuit responds to this detected condition as described before by providing a high signal to clamp control output 226 that causes NMOS main clamp transistor 222 to close (turn on) such that transistor 222 shunts the charge generated by the negative ESD event 390 from V_{DD} to V_{SS} via a shunt formed by main clamp conductive elements 227 and 229. At the same time the high signal on clamp control output 226 is also provided from main clamp control circuit 220 to the local clamp control circuit 285 of each circuit segment 360 as shown. Each of local clamp control circuits 285 responds to presence of a high signal on clamp control output 226 by producing a high signal output 221 to a corresponding NMOS local clamp transistor 283 that closes (turns on) to divert the charge differential generated by the negative ESD event 390 as current I_{ESD} from V_{DD} through node 297 to V_{SS} via corresponding local conductive elements 381 and 382. In this way, the charge resulting from a negative ESD event 390 is simultaneously diverted as current I_{ESD} from nodes 297 to reduce voltage of the source of each PMOS output transistor 210 relative to its bulk terminal, which reduces or substantially eliminates PMOS transistor snapback occurrence. At the same time, the ESD charge is dissipated by this routing of I_{ESD} in a simultaneous distributed manner through conductive elements 381 and 382 of each of the local clamp circuitries within each circuit segment 360, as well as shunted by conductive elements 227 and 229 of main clamp circuitry 270 to minimize adverse effects of V_{DD} and V_{SS} rail bus resistances 215 and 216.

Referring to FIG. 3 in more detail, when a negative ESD event 390 strikes at a given output signal pad 202₁, a negative potential is created for current travel toward pad 202₁ via conduction in ESD diode 208₁. Node 207₁ and the drain of PMOS output transistor element 210₁ of circuit segment 260₁ also see the negative potential induced on node 202₁. However, at the same time, current flows toward the negative potential at pad 202₁ from negative rail supply rail V_{SS} and is diverted at node 297₁ toward negative rail supply rail V_{SS} from positive supply rail V_{DD} through resistive element 380₁ and NMOS local clamp transistor 283₁ (and through other local clamp transistor elements 283 in respective circuit segments 360) and then through ESD diode 208₁ to struck pad 202₁. This current flow to supply rail V_{SS} from node 297₁ greatly reduces the emitter base voltage appearing across the parasitic PNP element 205₁ in circuit segment 360₁. Resistive element 380₁ may be sized and configured to sufficiently resist current flow from V_{DD} to node 297₁ to provide sufficient voltage reduction at the source of PMOS transistor 210₁ coupled to node 297₁ during the negative ESD event to reduce or substantially eliminate occurrence of avalanche breakdown and/or parasitic snapback across PMOS transistor 210₁ by reducing voltage drop across the emitter and base of the parasitic PNP bipolar junction transistor (BJT) 205 that is present at the PMOS output transistor element 210₁ during occurrence of negative ESD event 390 so as to prevent forward biasing of the parasitic BJT 205₁, while at the same time allowing sufficient conductivity of I_{ESD} to negative supply rail V_{SS} through resistive element 380₁ to distributively dissipate charge from ESD event 390. Placing NMOS local clamp transistors between nodes 297 and VSS differs from conventional circuit topology but also has the advantage of greatly reducing capacitive parasitic loading on the output node 202 of each of the circuit segments 360 in FIGS. 3.

It will be understood that resistive elements 380 may be any suitable component (resistor or other resistive component) or combination of resistive components that provide a desired electrical resistance to current flow during a negative ESD event 390 without interfering with operation of a PMOS output transistor 210 during normal output buffer circuitry operation and while at the same time allowing sufficient conductivity of I_{ESD} to negative supply rail V_{SS} through resistive element 380₁ to distributively dissipate charge from ESD event 390. In this regard, resistive elements 380 may be formed from drawn layers in a semiconductor process such as diffusion, polysilicon or metal layers and in one embodiment may exhibit a resistance value of from about 3 to about 30 ohms depending on the signaling requirements, it being understood that resistive elements 380 may have values greater than about 30 ohms or less than about 3 ohms in other embodiments.

It will also be understood that the above description of configuration and function of components of circuit segment 360₁ is exemplary and representative of similar components of each of other circuit segments 360₂ to 360_{N}.

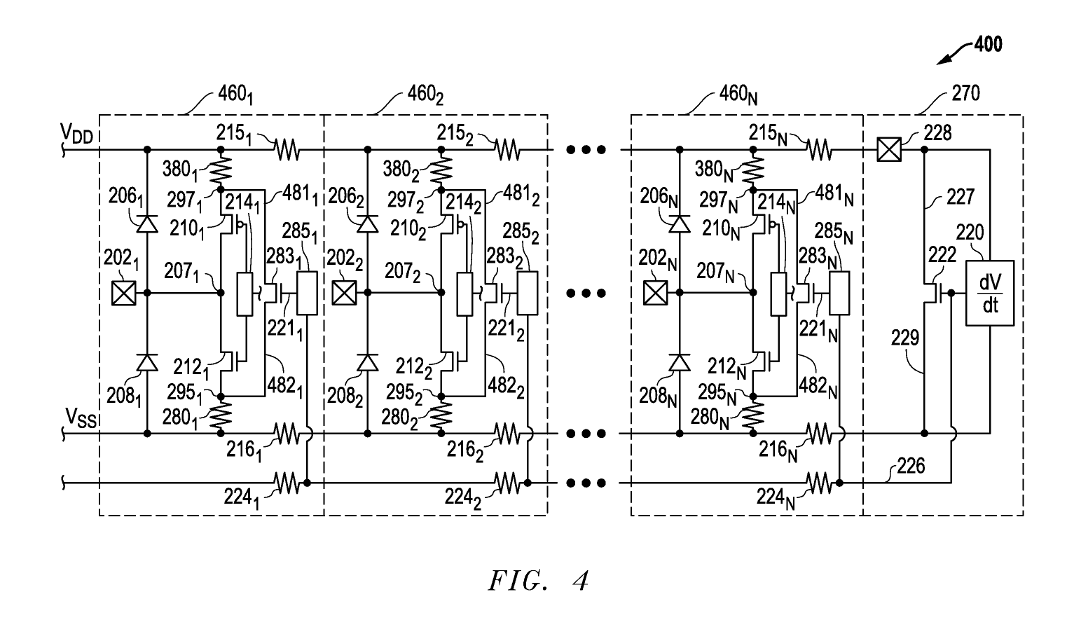

FIG. 4 illustrates another exemplary embodiment of a signal output circuitry 400 having multiple signal output circuit segments 460₁ to 460_{N} and CMOS output circuitry configured similarly to circuitry 200 of FIG. 2, except this time provided with a snapback inhibiting clamp circuit configuration to protect both the PMOS (PNP) output transistor 210 and NMOS (NPN) output transistor 212 of each of output circuit segments 460₁ to 460_{N} from parasitic snapback during occurrence of respective negative and positive ESD events on one of output signal pads 202. Similar to circuitry of FIGS. 2 and 3, each of signal output circuit segments 460₁ to 460_{N} is configured with local snapback inhibiting clamp circuitry that includes a respective local clamp control circuit 285 that is coupled to provide a local clamp control output 221 to the gate of a local NMOS clamp transistor 283.

As further shown in FIG. 4, each local NMOS clamp transistor 283 itself is coupled between respective conductive elements 481 and 482 so as to divert ESD current (I_{ESD}) from V_{DD} through respective source voltage reduction node 297 positioned between a source of the respective PMOS output transistor 210 and a respective voltage reduction resistive element 380 in a manner that acts to reduce voltage at the source of the PMOS output transistor element 210 relative to its bulk terminal (i.e., nwell) during the occurrence of a negative ESD event 390 in a manner described in relation to FIG. 3. Additionally, in circuitry 400 each local NMOS clamp transistor 283 is also coupled between respective conductive elements 481 and 482 so as to divert ESD current (I_{ESD}) from V_{DD} to a respective source voltage elevation node 295 positioned between a source of the respective NMOS output transistor 212 and a respective voltage elevation resistive element 280 in a manner that acts to elevate voltage at the source of the NMOS output transistor element 212 relative to its bulk terminal during the occurrence of a positive ESD event 290 in a manner described in relation to FIG. 2. Other components of circuitry 400 of FIG. 4 may have similar configuration and operation as corresponding components of circuitries 200 and 300 of FIGS. 2 and 3, respectively. Thus in FIG. 4, protection against snapback may be provided for both PMOS output transistor element 210 and NMOS output transistor element 212 of each circuit segment 460. Resistive elements 280 and 380 may be formed from drawn layers in a semiconductor process such as diffusion, polysilicon or metal layers and in one embodiment may exhibit a resistance value of from about 3 to about 30 ohms depending on the signaling requirements, it being understood that resistive elements 280 and 380 may have values greater than about 30 ohms or less than about 3 ohms in other embodiments.

It will also be understood that in an alternative embodiment, each of local clamp control circuits 285 of any of the embodiments of FIG. 2, 3 or 4 may be configured to operate independently in response to detection of the occurrence of an ESD event on a signal pad 202, i.e., without the presence of main clamp control circuit 220 and/or without receiving a control signal 226 from a main clamp control circuit 220. For example, one or more local clamp control circuits 285 may itself be configured to sense (or may be coupled to other separate circuitry that is configured to sense) the presence of the occurrence of a ESD event on signal pads 202 of circuit segments 260, e.g., by measuring the rate of change in voltage between V_{DD} and V_{SS} rails to sense rise in voltage versus time (dV/dt) between V_{DD} and V_{SS} rails. Examples of such suitable ESD event-sensing circuitry includes, but is not limited to, RC triggered high-pass or low-pass circuits which drive inverter stages to buffer and condition the detected signal.

While the invention may be adaptable to various modifications and alternative forms, specific embodiments have been shown by way of example and described herein. However, it should be understood that the invention is not intended to be limited to the particular forms disclosed. Rather, the invention is to cover all modifications, equivalents, and alternatives falling within the spirit and scope of the invention as defined by the appended claims. Moreover, the different aspects of the disclosed circuitry and methods may be utilized in various combinations and/or independently. Thus the invention is not limited to only those combinations shown herein, but rather may include other combinations.

What is claimed is:

1. A semiconductor circuit device, comprising:
at least first and second supply rails having opposite polarity;
at least one N-type metal-oxide-semiconductor (NMOS) or P-type metal-oxide-semiconductor (PMOS) transistor coupled between the first and second supply rails;
a resistive element coupled between the at least one transistor and the first supply rail with a current diversion node coupled between the at least one transistor and the resistive element;
local clamp circuitry coupled between the current diversion node and the second supply rail, the local clamp circuitry being configured to selectively shunt current between the second supply rail and the first supply rail through the current diversion node and the resistive element in response to an electrostatic discharge (ESD) event; and
a signal pad coupled between the first and second supply rails and also coupled between the at least one transistor and the second supply rail.

2. The circuit device of claim 1, further comprising at least one circuit segment that includes:
output buffer circuitry including the at least one NMOS or PMOS transistor coupled between the first and second supply rails, the output buffer circuitry further comprising the resistive element coupled between the at least one transistor of the output buffer circuitry and the first supply rail with the current diversion node coupled between the at least one transistor and the resistive element;
where the signal pad is coupled between the first and second supply rails and is also coupled to the output buffer circuitry at a first node with the at least one transistor being coupled between the first node and the resistive element;
where the local clamp circuitry is coupled between the current diversion node and the second supply rail, the local clamp circuitry being configured to selectively shunt current between the second supply rail and the first supply rail through the current diversion node and the resistive element in response to the ESD event;
a first ESD diode coupled between the signal pad and the first supply rail; and
a second ESD diode coupled between the signal pad and the second supply rail.

3. The device of claim 2, where the first power supply rail comprises a negative supply rail and the second supply rail comprises a positive supply rail; where the at least one transistor of the output buffer circuitry comprises a NMOS transistor coupled between the negative and positive supply rails with the resistive element being coupled between a source node of the NMOS transistor of the output buffer circuitry and the negative supply rail, the current diversion node being coupled between the source node of the NMOS transistor and the resistive element; where the first ESD diode is coupled between the signal pad and the first supply rail to prevent flow of current from the signal pad to the first power supply rail and to allow flow of current from the first power supply rail to the signal pad; and where the second ESD diode is coupled between the signal pad and the second supply rail to allow flow of current from the signal pad to the second power supply rail and to prevent flow of current from the second power supply rail to the signal pad.

4. The device of claim 3, where the output buffer circuitry of the at least one circuit segment further comprises a PMOS transistor coupled between the NMOS transistor and the positive supply rail with the signal pad coupled between the negative and positive supply rails at the first node.

5. The device of claim 2, where the first power supply rail comprises a positive supply rail and the second supply rail comprises a negative supply rail; where the output buffer circuitry of the at least one circuit segment includes a PMOS transistor coupled between the negative and positive supply rails with the resistive element being coupled between the source node of the PMOS transistor of the output buffer circuitry and the positive supply rail with the current diversion node coupled between the source of the PMOS transistor and the resistive element; where the first ESD diode is coupled between the signal pad and the first supply rail to allow flow of current from the signal pad to the first power supply rail and to prevent flow of current from the first power supply rail to the signal pad; and where the second ESD diode is coupled between the signal pad and the second supply rail to prevent flow of current from the signal pad to the second power supply rail and to allow flow of current from the second power supply rail to the signal pad.

6. The device of claim 5, where the output buffer circuitry of the at least one circuit segment further comprises a NMOS transistor coupled between the PMOS transistor and the negative supply rail with the signal pad coupled between the negative and positive supply rails at the first node.

7. The device of claim 2, where the first power supply rail comprises a negative supply rail and the second supply rail comprises a positive supply rail; where the at least one transistor of the output buffer circuitry comprises a NMOS transistor and a PMOS transistor coupled in series between the negative and positive supply rails with the PMOS transistor coupled between the NMOS transistor and the positive supply rail, and the first node coupled between the NMOS and PMOS transistors; where the resistive element is a first resistive element coupled between a source node of the NMOS transistor of the output buffer circuitry and the negative supply rail, the current diversion node being a first current diversion node coupled between the source node of the NMOS transistor and the first resistive element; and where the at least one circuit segment further comprises:
a second resistive element coupled between the source node of the PMOS transistor of the output buffer circuitry and the positive supply rail; and
a second current diversion node coupled between the source node of the PMOS transistor and the second resistive element of the output buffer circuitry;
where the local clamp circuitry is coupled in series between the first current diversion node and the second current diversion node, the local clamp circuitry being configured to selectively shunt current between the second supply rail and the first supply rail through the first and second current diversion nodes and the first and second resistive elements in response to the ESD event

8. The device of claim 2, where the at least one circuit segment comprises two or more circuit segments coupled in parallel between the first and second supply rails, each of the circuit segments comprising:
output buffer circuitry including at least one NMOS or PMOS transistor coupled between the first and second supply rails, the output buffer circuitry further comprising a resistive element coupled between the at least one transistor of the output buffer circuitry and the first supply rail with a current diversion node coupled between the at least one transistor and the resistive element;
a signal pad coupled between the first and second supply rails and also coupled to the output buffer circuitry at a first node with the at least one transistor being coupled between the first node and the resistive element; and
local clamp circuitry coupled between the current diversion node and the second supply rail, the local clamp circuitry being configured to selectively shunt current between the second supply rail and the first supply rail through the current diversion node and the resistive element in response to the ESD event.

9. The device of claim 8, where the local clamp circuitry is configured to selectively shunt current between the second supply rail and the first supply rail through the current diversion node and the resistive element in response to a clamp control signal; and where the semiconductor circuit device further comprises:
main clamp circuitry coupled between the first and second supply rails of the semiconductor device, the main clamp circuitry being configured to selectively shunt current between the first and second supply rails and to output the clamp control signal to the local clamp circuitry in response to detection of the occurrence of an electrostatic discharge (ESD) event on the signal pad to cause the local clamp circuitry to shunt current between the second supply rail and the first supply rail through the current diversion node and the resistive element.

10. The device of claim 8, where the first power supply rail comprises a negative supply rail and the second supply rail comprises a positive supply rail; where the at least one transistor of the output buffer circuitry of each given one of the two or more circuit segments comprises a NMOS transistor coupled between the negative and positive supply rails with the resistive element of the given circuit segment being coupled between a source node of the NMOS transistor of the output buffer circuitry of the given circuit segment and the negative supply rail; where the current diversion node of each of each given one of the circuit segments is coupled between the source node of the NMOS transistor and the resistive element of the given circuit segment; and where the output buffer circuitry of each given one of the circuit segments further comprises a PMOS transistor coupled between the NMOS transistor of the given circuit segment and the positive supply rail with the signal pad of the given circuit segment being coupled between the negative and positive supply rails at the first node of the given circuit segment.

11. The device of claim 8, where the first power supply rail comprises a negative supply rail and the second supply rail comprises a positive supply rail; where the at least one transistor of the output buffer circuitry of each given one of the two or more circuit segments comprises a PMOS transistor coupled between the negative and positive supply rails with the resistive element of the given circuit segment being coupled between a source node of the PMOS transistor of the output buffer circuitry of the given circuit segment and the positive supply rail; where the current diversion node of each of each given one of the circuit segments is coupled between the source node of the PMOS transistor and the resistive element of the given circuit segment; and where the output buffer circuitry of each given one of the circuit segments further comprises a NMOS transistor coupled between the PMOS transistor of the given circuit segment and the negative supply rail with the signal pad of the given circuit segment being coupled between the negative and positive supply rails at the first node of the given circuit segment.

12. The device of claim 8, where the first power supply rail comprises a negative supply rail and the second supply rail comprises a positive supply rail; where the at least one transistor of the output buffer circuitry of each given one of the two or more circuit segments comprises a NMOS transistor and a PMOS transistor coupled in series between the negative and positive supply rails with the PMOS transistor coupled between the NMOS transistor of the given circuit segment and the positive supply rail, and the first node of the given circuit segment coupled between the NMOS and PMOS transistors of the given circuit segment; where the resistive element of the given circuit segment is a first resistive element coupled between a source node of the NMOS transistor of the output buffer circuitry of the given circuit segment and the negative supply rail, the current diversion node of the given circuit segment being a first current diversion node coupled between the source node of the NMOS transistor and the first resistive element of the given circuit segment; and where each given one of the two or more circuit segments further comprises:
a second resistive element coupled between the source node of the PMOS transistor of the output buffer circuitry of the given circuit segment and the positive supply rail; and
a second current diversion node coupled between the source node of the PMOS transistor and the second resistive element of the output buffer circuitry of the given circuit segment;
where the local clamp circuitry of the given circuit segment is coupled in series between the first current diversion node and the second current diversion node, the local clamp circuitry of the given circuit segment being configured to selectively shunt current between the second supply rail and the first supply rail through the first and second current diversion nodes and the first and second resistive elements of the given circuit segment in response to the ESD event.

13. The device of claim 1, where the local clamp circuitry is configured to selectively shunt current between the second supply rail and the first supply rail through the current diversion node and the resistive element in response to a clamp control signal; and where the semiconductor circuit device further comprises:
main clamp circuitry coupled between the first and second supply rails of the semiconductor device, the main clamp circuitry being configured to selectively shunt current between the first and second supply rails and to output the clamp control signal to the local clamp circuitry in response to detection of the occurrence of an electrostatic discharge (ESD) event on the signal pad to cause the local clamp circuitry to shunt current between the second supply rail and the first supply rail through the current diversion node and the resistive element.

14. A method, comprising:
detecting occurrence of an electrostatic discharge (ESD) event on a signal pad coupled between first and second supply rails having opposite polarity; and
selectively shunting current between the second supply rail and the first supply rails through a current diversion node and a resistive element of local clamp circuitry in response to the ESD event, the resistive element being coupled between at least one N-type metal-oxide-semiconductor (NMOS) or P-type metal-oxide-semiconductor (PMOS) transistor and the first supply rail with the current diversion node coupled between the at least one transistor and the resistive element, and the at least one transistor being further coupled between the first and second supply rails with the signal pad coupled between the at least one transistor and the second supply rail.

15. The method of claim 14, where at least one circuit segment comprises the output buffer circuitry that includes the at least one NMOS or PMOS transistor coupled between the first and second supply rails, the output buffer circuitry further comprising the resistive element coupled between the at least one transistor of the output buffer circuitry and the first supply rail with the current diversion node coupled between the at least one transistor and the resistive element; where the signal pad is coupled between the first and second supply rails with a first ESD diode being coupled between the signal pad and the first supply rail and a second ESD diode being coupled between the signal pad and the second supply rail; where the signal pad is also coupled to the output buffer circuitry at the first node with the at least one transistor being coupled between the first node and the resistive element; where the local clamp circuitry is coupled between the current diversion node and the second supply rail; and where the method further comprises:
selectively shunting current between the second supply rail and the first supply rail through the current diversion node and the resistive element in response to the ESD event.

16. The method of claim 15, where the first power supply rail comprises a negative supply rail and the second supply rail comprises a positive supply rail; where the at least one transistor of the output buffer circuitry comprises a NMOS transistor coupled between the negative and positive supply rails with the resistive element being coupled between a source node of the NMOS transistor of the output buffer circuitry and the negative supply rail, the current diversion node being coupled between the source node of the NMOS transistor and the resistive element; where the output buffer circuitry of the at least one circuit segment further comprises a PMOS transistor coupled between the NMOS transistor and the positive supply rail with the signal pad coupled between the negative and positive supply rails at the first node; where the first ESD diode is coupled between the signal pad and the first supply rail to prevent flow of current from the signal pad to the first power supply rail and to allow flow of current from the first power supply rail to the signal pad; and where the second ESD diode is coupled between the signal pad and the second supply rail to allow flow of current from the signal pad to the second power supply rail and to prevent flow of current from the second power supply rail to the signal pad.

17. The method of claim 15, where the first power supply rail comprises a positive supply rail and the second supply rail comprises a negative supply rail; where the first ESD diode is coupled between the signal pad and the first supply rail to allow flow of current from the signal pad to the first power supply rail and to prevent flow of current from the first power supply rail to the signal pad; and where the second ESD diode is coupled between the signal pad and the second supply rail to prevent flow of current from the signal pad to the second power supply rail and to allow flow of current from the second power supply rail to the signal pad; and where the output buffer circuitry of the at least one circuit segment further comprises:
a PMOS transistor coupled between the negative and positive supply rails with the resistive element being coupled between the source node of the PMOS transistor of the output buffer circuitry and the positive supply rail with the current diversion node coupled between the source of the PMOS transistor and the resistive element; and a NMOS transistor coupled between the PMOS transistor and the negative supply rail with the signal pad coupled between the negative and positive supply rails at the first node.

18. The method of claim 15, where the first power supply rail comprises a negative supply rail and the second supply rail comprises a positive supply rail; where the at least one transistor of the output buffer circuitry comprises a NMOS transistor and a PMOS transistor coupled in series between the negative and positive supply rails with the PMOS transistor coupled between the NMOS transistor and the positive supply rail, and the first node coupled between the NMOS and PMOS transistors; where the resistive element is a first resistive element coupled between a source node of the NMOS transistor of the output buffer circuitry and the negative supply rail, the current diversion node being a first current diversion node coupled between the source node of the NMOS transistor and the first resistive element; and where the at least one circuit segment further comprises:
a second resistive element coupled between the source node of the PMOS transistor of the output buffer circuitry and the positive supply rail; and
a second current diversion node coupled between the source node of the PMOS transistor and the second resistive element of the output buffer circuitry;
where the local clamp circuitry is coupled in series between the first current diversion node and the second current diversion node; and
where the method further comprises selectively shunting current between the second supply rail and the first supply rail through the first and second current diversion nodes and the first and second resistive elements in response to the ESD event.

19. The method of claim 15, where the at least one circuit segment comprises two or more circuit segments coupled in parallel between the first and second supply rails, each of the circuit segments comprising:
output buffer circuitry including at least one NMOS or PMOS transistor coupled between the first and second supply rails, the output buffer circuitry further comprising a resistive element coupled between the at least one transistor of the output buffer circuitry and the first supply rail with a current diversion node coupled between the at least one transistor and the resistive element;
a signal pad coupled between the first and second supply rails and also coupled to the output buffer circuitry at a first node with the at least one transistor being coupled between the first node and the resistive element; and
local clamp circuitry coupled between the current diversion node and the second supply rail;
where the method further comprises:
selectively shunting current between the second supply rail and the first supply rail through the current diversion node and the resistive element of each of the two or more circuit segment in response to the ESD event.

20. The method of claim 19, further comprising:
selectively shunting current through a main clamp circuitry conductive path between the second supply rail and the first supply rail and outputting a clamp control signal in response to the detection of the occurrence of the ESD event on the signal pad; and
selectively shunting current between the second supply rail and the first supply rail through the current diversion node and the resistive element of each of the two or more circuit segment in response to the clamp control signal.

21. The method of claim 19, where the first power supply rail comprises a negative supply rail and the second supply rail comprises a positive supply rail; where the at least one transistor of the output buffer circuitry of each given one of the two or more circuit segments comprises a NMOS transistor coupled between the negative and positive supply rails with the resistive element of the given circuit segment being coupled between a source node of the NMOS transistor of the output buffer circuitry of the given circuit segment and the negative supply rail; where the current diversion node of each of each given one of the circuit segments is coupled between the source node of the NMOS transistor and the resistive element of the given circuit segment; and where the output buffer circuitry of each given one of the circuit segments further comprises a PMOS transistor coupled between the NMOS transistor of the given circuit segment and the positive supply rail with the signal pad of the given circuit segment being coupled between the negative and positive supply rails at the first node of the given circuit segment.

22. The method of claim 19, where the first power supply rail comprises a negative supply rail and the second supply rail comprises a positive supply rail; where the at least one transistor of the output buffer circuitry of each given one of the two or more circuit segments comprises a PMOS transistor coupled between the negative and positive supply rails with the resistive element of the given circuit segment being coupled between a source node of the PMOS transistor of the output buffer circuitry of the given circuit segment and the positive supply rail; where the current diversion node of each of each given one of the circuit segments is coupled between the source node of the PMOS transistor and the resistive element of the given circuit segment; and where the output buffer circuitry of each given one of the circuit segments further comprises a NMOS transistor coupled between the PMOS transistor of the given circuit segment and the negative supply rail with the signal pad of the given circuit segment being coupled between the negative and positive supply rails at the first node of the given circuit segment.

23. The method of claim 19, where the first power supply rail comprises a negative supply rail and the second supply rail comprises a positive supply rail; where the at least one transistor of the output buffer circuitry of each given one of the two or more circuit segments comprises a NMOS transistor and a PMOS transistor coupled in series between the negative and positive supply rails with the PMOS transistor coupled between the NMOS transistor of the given circuit segment and the positive supply rail, and the first node of the given circuit segment coupled between the NMOS and PMOS transistors of the given circuit segment; where the resistive element of the given circuit segment is a first resistive element coupled between a source node of the NMOS transistor of the output buffer circuitry of the given circuit segment and the negative supply rail, the current diversion node of the given circuit segment being a first current diversion node coupled between the source node of the NMOS transistor and the first resistive element of the given circuit segment; and where each given one of the two or more circuit segments further comprises:
a second resistive element coupled between the source node of the PMOS transistor of the output buffer circuitry of the given circuit segment and the positive supply rail; and
a second current diversion node coupled between the source node of the PMOS transistor and the second resistive element of the output buffer circuitry of the given circuit segment;
where the local clamp circuitry of the given circuit segment is coupled in series between the first current diversion node and the second current diversion node; and
where the method further comprises selectively shunting current between the second supply rail and the first supply rail through the first and second current diversion nodes and the first and second resistive elements of the given circuit segment in response to the ESD event.

24. The method of claim 14, further comprising:
selectively shunting current through a main clamp circuitry conductive path between the second supply rail and the first supply rail and outputting a clamp control signal in response to the detection of the occurrence of the ESD event on the signal pad; and
selectively shunting current between the second supply rail and the first supply rails through a current diversion node and a resistive element of local clamp circuitry in response to the clamp control signal, the resistive element being coupled between at least one N-type metal-oxide-semiconductor (NMOS) or P-type metal-oxide-semiconductor (PMOS) transistor and the first supply rail with the current diversion node coupled between the at least one transistor and the resistive element, and the at least one transistor being further coupled between the first and second supply rails with the signal pad coupled between the at least one transistor and the second supply rail.
